(19) United States
(12) Patent Application Publication
(10) Pub. No.: US 2009/0045424 A1
(43) Pub. Date: Feb. 19, 2009

(54) SILICONE BASED CIRCUIT BOARD INDICATOR LED LENS

(76) Inventor: RICHARD LISKOFF, Manasquan, NJ (US)

Correspondence Address: PATTERSON & SHERIDAN L.L.P. NJ Office, 595 SHREWSBURY AVE, STE 100, FIRST FLOOR, SHREWSBURY, NJ, 07702, US

(21) Appl. No.: 12/189,018

(22) Filed: Aug. 8, 2008

Related U.S. Application Data
(60) Provisional application No. 60/955,178, filed on Aug. 10, 2007.

(51) Int. Cl. H01L 33/00

(52) U.S. Cl. 257/98; 438/27; 257/E33.067

(57) ABSTRACT

The present invention relates generally to a light transmitting device. In one embodiment, the light transmitting device includes a light emitting diode (LED) chip, a surface mounting device and a lens comprising a silicone based material, wherein a portion of the lens achieves a total internal reflection of a light emitted by the LED chip.

### RELATED APPLICATIONS

This application claims priority under 35 U.S.C. § 119(e) to U.S. provisional patent application Ser. No. 60/955,178, filed on Aug. 10, 2007, which is hereby incorporated by reference in its entirety.

### FIELD OF THE INVENTION

The present invention relates generally to the use of silicone in a light transmitting device.

### BACKGROUND OF THE INVENTION

Circuit boards for many different applications utilize various light emitting diodes (LEDs) as indicator lights. The indicator LEDs are useful to let a user know a process is occurring, indicating a device is powered on or providing other notifications.

When fabricating the circuit boards with indicator LEDs, the LEDs are typically encased in a light transmitting material. Current light transmitting materials are insufficient for use with LEDs used as indicators on circuit boards because they cannot withstand the high temperatures associated with a reflow soldering process used to couple the indicator LEDs to the circuit board.

### SUMMARY OF THE INVENTION

In one embodiment, the present invention is directed towards a light transmitting device used with a light emitting diode (LED). In one embodiment, the light transmitting device comprises a LED chip, a surface mounting device and a lens comprising a silicone based material, wherein a portion of the lens achieves total internal reflection of a light emitted by the LED chip.

In one embodiment, the present invention also provides an alternate embodiment of an light transmitting device. In one embodiment, the light transmitting device comprises a LED assembly, a surface mounting device coupled to the LED assembly and a lens comprising a silicone based material that fills a cavity formed by the surface mounting device and the LED assembly and reflects a light emitted by the LED assembly.

In one embodiment, the present invention provides a method for providing a light transmitting device. The method comprises providing a surface mounting device, coupling a LED chip to the surface mounting device such that a cavity is created by the at least one surface of the surface mounting device and the LED chip and filling the cavity with a portion of a lens comprising a silicone based material that achieves a total internal reflection.

### BRIEF DESCRIPTION OF THE DRAWINGS

So that the manner in which the above recited features of the present invention can be understood in detail, a more particular description of the invention may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts a cutaway view of an exemplary embodiment of a light transmitting device;

FIG. 2 depicts an exploded isometric view of the light transmitting device;

FIG. 3 depicts a flowchart for an exemplary method for providing the light transmitting device;

FIG. 4 depicts an exploded isometric view of an exemplary light transmitting device having a stack of two lenses and two LED chips;

FIG. 5 depicts an exploded isometric view of an exemplary light transmitting device having a stack of three lenses and three LED chips; and

FIG. 6 depicts an exploded isometric view of an exemplary light transmitting device.

### DETAILED DESCRIPTION

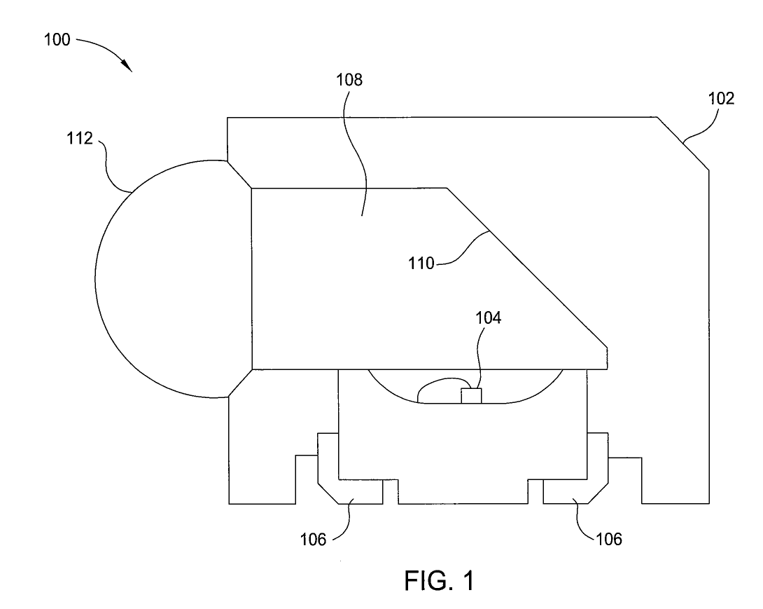

FIG. 1 illustrates a cutaway view of an exemplary light transmitting device 100 of the present invention. In one embodiment, the light transmitting device 100 may have a footprint appropriate for being mounted onto circuit boards as an indicator LED lens. However, those skilled in the art will recognize that embodiments of the present invention may be applicable to various sizes of light transmitting device 100 without departing from the scope of the invention. The light transmitting device 100 comprises a surface mounting device (SMD) 102 that is coupled to an LED chip or LED assembly 104 and a lens 112. Hereinafter, LED chip and LED assembly may be used interchangeably. The SMD 102 may be constructed from any material suitable for use with light transmitting devices 100. The LED chip 104 may have any type of LED suitable for use as an indicator lighting device. The LED chip 104 is coupled to mounting pads 106.

The SMD 102 is coupled to the LED chip 104 to form a cavity 108. The cavity 108 may be filled by the lens 112 made of silicone based materials. A distance between the LED chip 104 and the lens 112 may vary. For example, a tail 110 of the lens may touch the LED chip 104 at a minimum distance to a maximum distance that allows the tail 110 of the lens 112 to still achieve total internal reflection (TIR) discussed below.

For example, as the distance between the LED chip 104 and an input side of the tail 110 increases, the range of collection angles or acceptance angles becomes narrower. As a result, output light intensity suffers. In one embodiment, the maximum allowable distance for acceptable brightness at an output side of the lens 112 was found to be 0.01 millimeters. However, if the refractive index of the silicone based material is less than that of the surrounding medium, TIR will not take place and light emitted from the LED chip 104 is not guided back into the tail 110 of the lens 112. Thus, it is within the embodiment of the present invention that LED chip 104, SMD 102 and the lens 112 may be coupled such that the tail 110 of the lens 112 may not necessarily contact a top of the LED chip 104.

The lens 112 may be pre-fabricated by injection molding using silicone based materials. The way the lens 112 is injection molded and the silicone based materials lead to a lens 112 that performs better optically. In one embodiment, the lens 112 may be injection molded via single or multi-cavity tooling with a center sprue design and radial cavities projecting from the radial sprue. The mold design helps to reduce flow lines and aesthetic defects. The number of cavities may vary from one to 200, for example.

Processing times and temperatures is a function of the type of silicone based material used. However, one skilled in the art will easily recognize the appropriate processing times and temperatures based on the silicone based material used.

The silicone based material may be any type of siloxane including polysiloxane having one or more organic groups or side chains such as methyl, ethyl or phenyl groups or silicone elastomers. The silicone based material may include any percentage of silicone as long as the silicone is optical grade. In other words, the silicone may contain impurities or other compounds as long as the silicone based material is optical grade. Optical grade is defined as having characteristics including, but not limited to, sufficient transparency or clarity for optical transmission. In one embodiment, the silicone based material used to form the lens 112 may be an optical grade silicone rubber.

Of the vast number of possible materials that may be used to fill the cavity 108, silicone based materials are found to be unexpectedly superior to many of the vast number of alternative materials used for the LED lens 112. For example, one alternative to silicone based materials is to use thermoset materials. Thermoset materials are typically resins such as, for example, epoxy resin, polyester resin or phenol formaldehyde resin. These thermoset materials are capable of withstanding high temperatures, but are very difficult to consistently mold without visual imperfections due to bubbling and flashing during processing and the brittle nature of thermoset materials.

However, silicone based materials can withstand the high temperatures associated with the reflow soldering process used to couple the light transmitting device 100 to a circuit board (not shown). Moreover, silicone based materials are much easier to process and can be injection molded without introducing visual imperfections. As a result, silicone based materials are less costly to process than thermoset materials. As a result, a higher quality light transmitting device 100 is produced.

The lens 112 contains a tail 110 that is “plugged” into the cavity 108. That is, in one embodiment, the shape of the tail may be substantially similar to the shape of the cavity 108. The tail 110 may be molded, cut or fabricated in any shape or in any angle such that the tail 110 of the lens 112 achieves TIR of a light emitted by the LED chip 104. In one embodiment, the tail 110 may be molded, cut or fabricated to form a prism shape as depicted in FIG. 1. For example, a 45° angle may be shaped into the tail 110 of the lens 112 such that the light emitted by the LED chip 104 is re-directed, moved or reflected in a direction perpendicular to the light emitted by the LED chip 104 out through the lens 112. In other words, in one embodiment illustrated by FIG. 1, the light emitted by the LED chip 104 may be angled 90° relative to the direction of the light emitted by the LED chip 104.

One skilled in the art will recognize that the tail 110 may be molded, cut or fabricated in any manner to form any shape such that the tail 110 of the lens 112 achieves TIR. For example, the tail 110 may be cut to form an angled shape, a curved shape, a parabolic shape, a radial shape and the like. Moreover, the lens 112 may be positioned relative to the LED chip 104 such that the light emitted by the LED chip 104 may be moved, re-directed or reflected in any desired direction. For example, the lens 112 may be positioned relative to the LED chip 104 to move, re-direct or reflect the light emitted by the LED chip 104 at a 45° angle or simply straight through as a light pipe. The examples provided above should not be interpreted as being limiting with respect to the shape of the tail 110, a positioning of the lens 112 relative to the LED chip 104 or in what direction the light emitted from the LED chip 104 is moved, re-directed or reflected.

In addition, the lens 112 may also be various shapes. For example, the lens 112 may be a circular shape, a polygon shape and the like. The lens 112 may also have a textured surface where the light is emitted to obtain better uniformity of the light output from the lens 112.

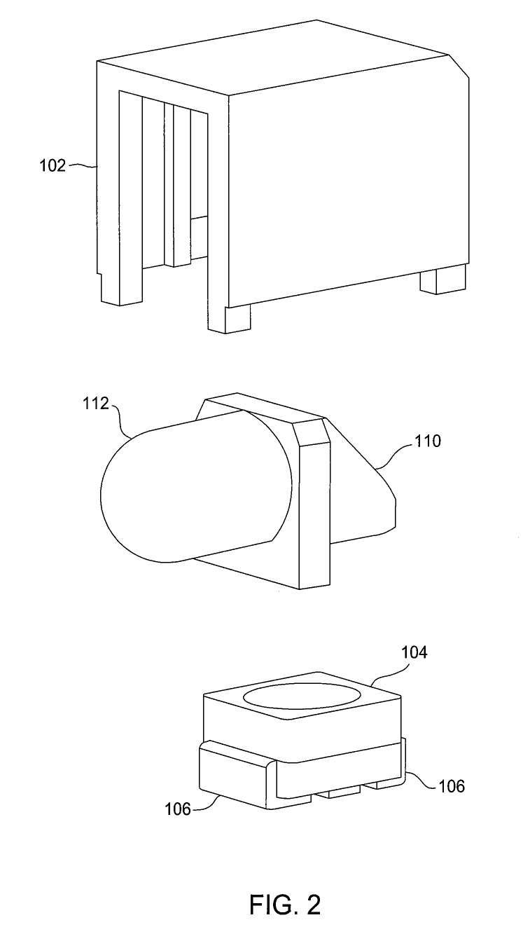

FIG. 2 illustrates an exploded isometric view of the light transmitting device 100. The light transmitting device may be viewed as three different components including the SMD 102, the lens 112 and the LED chip 104. In one embodiment, the light transmitting device 100 may be assembled by coupling the SMD 102, the lens 112 and the LED chip 104 to one another.

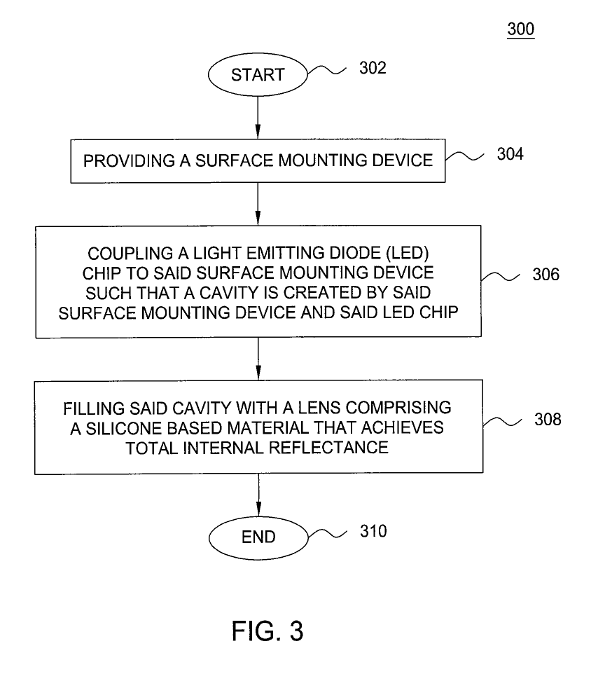

FIG. 3 illustrates a method 300 for providing a light transmitting device 100. The method begins at step 302. At step 304, the method provides a surface mounting device (SMD) 102.

Subsequently, at step 304, the method 300 couples a light emitting diode (LED) chip 104 to the SMD 102 such that a cavity is created by the SMD 102 and the LED chip 104.

At step 306, the method 300 fills or plugs the cavity 108 with a lens 112 comprising a silicone based material that achieves total internal reflectance. As discussed above, the lens 112 may be any shape that achieves total internal reflectance. Moreover as discussed above, a tail 110 of the lens 112 may be molded, cut or fabricated such that the tail 110 of the lens 112 may be in a shape substantially similar to the shape of the cavity 108.

As discussed above, the LED chip 104 may be positioned relative to the lens 112, such that a light emitted by the LED chip 104 may be moved, re-directed or reflected by the lens 112 in any desired direction. The method 300 concludes with step 310.

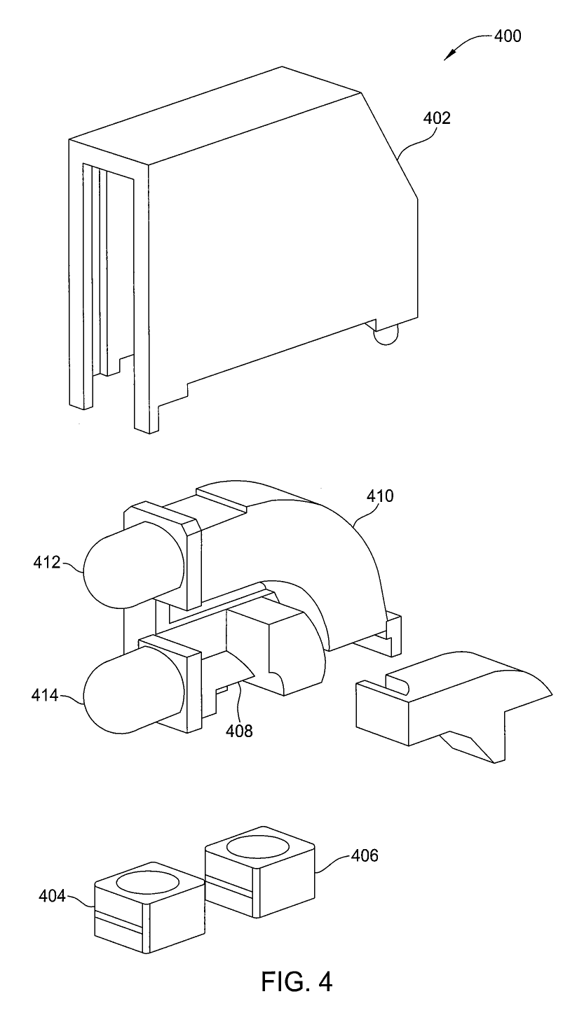

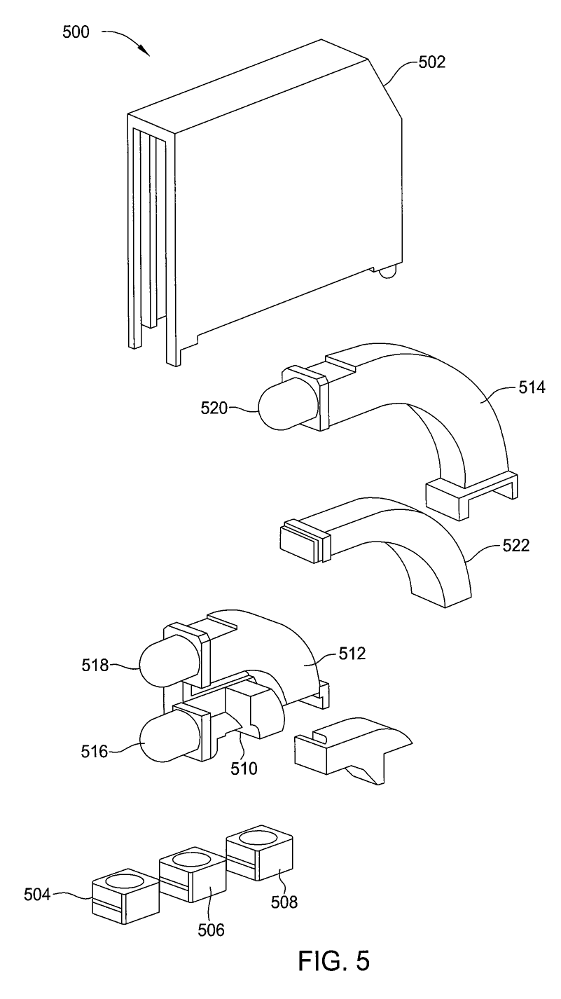

Moreover, the light transmitting device 100 may be manufactured with the lens 112 made of silicone based material in multiple stacks or arrays as illustrated by FIGS. 4 and 5. FIG. 4 illustrates a light transmitting device 400 having an SMD 402 that is modified in size to accommodate the stack of two lenses 412 and 414. The lenses 412 and 414 may be molded, cut or fabricated from silicone based materials. The silicone based materials may be any silicone based material similar to those described above for lens 112. In one embodiment as illustrated by FIG. 4, the stack of two lenses 412 and 414 may be injection molded as a single piece. Similar to the embodiment depicted in FIGS. 1 and 2, a first tail 410 is molded, cut or fabricated to be substantially a same shape as a cavity within the SMD 102. In addition both the first tail 410 and a second tail 408 may be molded, cut or fabricated in any shape such that each of the lenses 412 and 414 achieve TIR.

In addition, the light transmitting device 400 has two LED chips 404 and 406. The stack of lenses 412 and 414 may be molded, cut or fabricated such that each of the lenses 412 and 414 may be positioned with respect to a relative LED chips 404 and 406 such that TIR is achieved. For example in one embodiment, the LED chip 404 may emit light through the lens 414 and the LED chip 406 may emit light through the lens 412.

FIG. 5 illustrates one embodiment of a light transmitting device 500 having a stack of three lenses 516, 518 and 520. The lenses 516, 518 and 520 may be molded, cut or fabricated from silicone based materials. The silicone based materials may be any silicone based material similar to those described above for lens 112. The SMD 502 may be modified in size to accommodate the stack of three lenses 516, 518 and 520.

Notably different than the embodiment illustrated in FIG. 4, FIG. 5 illustrates that the lenses 516, 518 and 520 may be manufactured as one or more separate pieces. For example, in one embodiment illustrated in FIG. 5, lenses 516 and 518 are manufactured as a single piece having a tail 510 and 512, respectively and lens 520 is manufactured as a separate piece having a tail 514. A member 522 may be used to support the lens 520 and to properly align and space the lens 520 horizontally with respect to the LED chip 508 and vertically with respect to the lenses 516 and 518. One skilled in the art will recognize that the stack of three lenses 516, 518 and 520 may be manufactured as a single piece, three separate pieces or as lens 516 being a separate lens and lenses 518 and 520 being a single piece.

The tails 510, 512, and 514 may be molded, cut or fabricated in any shape to achieve TIR. In addition, the light transmitting device 500 has three LED chips 504, 506 and 508. The stack of lenses 516, 518 and 520 may be molded, cut or fabricated such that each of the lenses 516, 518 and 520 may be positioned with respect to a relative LED chip 504, 506 and 508 such that TIR is achieved. For example in one embodiment, the LED chip 504 may emit light through the lens 516, the LED chip 506 may emit light through the lens 518 and the LED chip 508 may emit light through the lens 520.

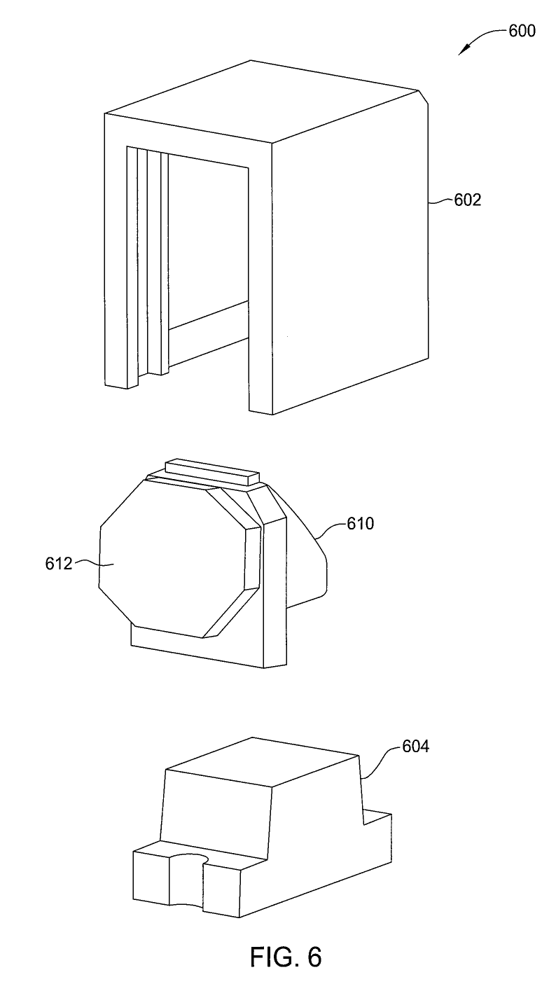

FIG. 6 illustrates an exemplary embodiment of a light transmitting device 600. The light transmitting device 600 is similar to that of light transmitting device 100 except for that a lens 612 is of a different shape than lens 112. As discussed above, the lenses 112 and 612 may be in any shape desired such a circular shape, a polygon shape and the like.

The light transmitting device 600 also comprises a SMD 602 modified to accommodate the size and shape of the lens 612, a tail 610 of the lens 612 and an LED chip 604. The SMD 602, the lens 612 and the LED chip 604 may be coupled together in a similar fashion as that of the SMD 102, the lens 112 and the LED chip 104 of the light transmitting device 100.

While various embodiments have been described above, it should be understood that they have been presented by way of example only, and not limitation. Thus, the breadth and scope of a preferred embodiment should not be limited by any of the above-described exemplary embodiments, but should be defined only in accordance with the following claims and their equivalents.

What is claimed is:

1. A light transmitting device, comprising:
a light emitting diode (LED) chip;
a surface mounting device, coupled to said LED chip; and
a lens comprising a silicone based material coupled to said surface mounting device, wherein a portion of said lens achieves a total internal reflection of a light emitted by said LED chip.

2. The light transmitting device of claim 1, wherein said silicone based material comprises an optical grade silicone based material.

3. The light transmitting device of claim 2, wherein said silicone based material comprises an optical grade silicone rubber.

4. The light transmitting device of claim 1, wherein said lens has a shape that achieves said total internal reflection, said shape comprising at least one of: a prism shape, an angled shape, a curved shape, a parabolic shape or a radial shape.

5. The light transmitting device of claim 1, wherein said lens fills a cavity formed by said surface mounting device and said LED chip.

6. The light transmitting device of claim 1, wherein said lens is positioned relative to said LED chip such that said light emitted by said LED chip is reflected through said lens and outputted in a desired direction.

7. The light transmitting device of claim 6, wherein said desired direction is perpendicular to a direction of said light emitted from said LED chip.

8. The light transmitting device of claim 6, wherein said desired direction is angled 90 degrees relative to said light emitted from said LED chip.

9. A light transmitting device, comprising:
a light emitting diode (LED) assembly;
a surface mounting device coupled to said LED assembly; and
a lens comprising a silicone based material that fills a cavity formed by said surface mounting device and said LED assembly and reflects a light emitted by said LED assembly.

10. The light transmitting device of claim 9, wherein said silicone based material comprises an optical grade silicone based material.

11. The light transmitting device of claim 10, wherein said silicone based material comprises an optical grade silicone rubber.

12. The light transmitting device of claim 9, wherein a portion of said lens has a shape that achieves a total internal reflection, said shape comprising at least one of: a prism shape, an angled shape, a curved shape, a parabolic shape or a radial shape.

13. The light transmitting device of claim 9, wherein said lens is positioned relative to said LED assembly such that said light emitted by said LED assembly is reflected through said lens and outputted in a desired direction.

14. The light transmitting device of claim 13, wherein said desired direction is perpendicular to a direction of said light emitted by said LED assembly.

15. The light transmitting device of claim 13, wherein said desired direction is angled 90 degrees relative to said light emitted by said LED assembly.

16. A method for providing a light transmitting device, comprising:
providing a surface mounting device;
coupling a light emitting diode (LED) chip to said surface mounting device such that a cavity is created by said surface mounting device and said LED chip; and
filling said cavity with a portion of a lens comprising a silicone based material that achieves a total internal reflection.

17. The method of claim 16, wherein said silicone based material comprises an optical grade silicone based material.

18. The method of claim 17, wherein said silicone based material comprises an optical grade silicone rubber.

19. The method of claim 16, wherein said lens has a shape that achieves said total internal reflection, said shape comprising at least one of: a prism shape, an angled shape, a curved shape, a parabolic shape or a radial shape.

20. The method of claim 16, further comprising:
positioning said lens relative to said LED chip such that a light emitted by said LED chip is reflected through said lens and outputted in a desired direction.
